(19) United States
(12) Patent Application Publication
(10) Pub. No.: US 2010/0132190 A1
(43) Pub. Date: Jun. 3, 2010

(54) INJECTION TOOL FOR ENCAPSULATING ELECTRONIC CIRCUITS WITH LIGHT SOURCES, AND RELATED ENCAPSULATION PROCESSES

(75) Inventors: Davide Grosso, Treviso (IT); Matteo Toscan, Maser (Treviso) (IT)

Correspondence Address: Viering, Jentschura & Partner - OSR, 3770 Highland Ave., Suite 203, Manhattan Beach, CA, 90266, US

(73) Assignee: OSRAM GESELLSCHAFT MIT BESCHRAENKTER HAFTUNG, Muenchen (DE)

(21) Appl. No.: 12/625,631

(22) Filed: Nov. 25, 2009

(30) Foreign Application Priority Data
Nov. 26, 2008 (EP) EP08170026

(51) Int. Cl. H05K 3/30; B23P 19/00

(52) U.S. Cl. 29/841; 29/739

(57) ABSTRACT

An injection tool for encapsulating an electronic circuit with a printed circuit board and at least one light source arranged thereon. The injection tool includes a support structure for supporting the electronic circuit within the injection tool and protection structure for protecting the light emitting surface of at least one light source from encapsulation material. At least one of the support and/or protection structures is mobile for compensating for dimensional tolerances in the electronic circuit.

### CROSS-REFERENCES TO RELATED APPLICATIONS

This application claims the benefit of European Patent Application No. EP08170026, filed Nov. 26, 2008.

### TECHNICAL FIELD

This disclosure relates to techniques for encapsulating electronic circuits and, more specifically, to a low-pressure, hot-melt moulding process of an electronic circuit comprising at least one Light Emitting Diode (LED) module.

### BACKGROUND

LED modules are increasingly used for lighting applications, such as for home environments. Such LED modules are usually mounted together with other electronic components, such as a driver circuit and wires, on a Printed Circuit Board (PCB). An encapsulation process may be used in order to improve the reliability and mechanical stability of the circuit.

For example, a low-pressure, hot-melt moulding process may be used to seal the electronic components mounted on the PCB with a polyamide material.

FIG. 1 shows an electronic circuit produced by such an encapsulation process. In such a process, a PCB 2 having mounted thereon at least one LED device L (two such components are shown in FIG. 1) is arranged in a tool 1. The PCB is retained in the tool 1 by means of a support structure 14. Subsequently, a melted polyamide material M is injected into the tool 1 in order to “seal”, i.e. cover the PCB 2. The tool 1 usually comprises also one or more protection elements 10 for protecting the light emitting surface of the LED device L.

Due to dimensional tolerances of the components (e.g. the LED device height or PCB thickness) and process variables (e.g. solder paste quantity and thickness), the total distance between the bottom side of the PCB (which is in contact with the fixed support 14) and the top side of the LED device (which is protected by means of the protection elements 10) may vary. Such protections 10 and supports 14 being fixed imply a high risk of damaging the LED device(s) or to leave between the surface of the LED device(s) L and the protection 10 an empty space where encapsulation material M may penetrate and thus cover the light emitting surface of the LED device.

### SUMMARY

An object of the invention is to provide techniques and apparatuses for encapsulating an electronic circuit that overcome the drawbacks mentioned in the foregoing.

That object is achieved by an injection tool for encapsulating an electronic circuit having the features set forth in the claims that follows. Embodiments also relate to corresponding processes for encapsulating an electronic circuit.

The claims form an integral part of the disclosure of the invention as provided herein.

In an embodiment, the arrangement as described herein is an injection tool for encapsulating an electronic circuit comprising at least one light source, such as a LED device.

In an embodiment, this tool is used in a low-pressure, hot-melt moulding encapsulating process.

In an embodiment, polyamide material, such as Macromel OM641 by Henkel, is melted in a pot at a temperature of approximately 220° C. and then injected into the tool in order to seal and to cover all the conductive parts. Thus the electronic circuit may be insulated and protected from water condensation and corresponding corrosion.

In an embodiment, the tool is a stainless steel tool, such as an 8 cavities stainless steel tool.

In an embodiment, an active protection system is used for the light source.

In an embodiment, the protection and/or the support structure of the tool are mobile in order perfectly close the form on the electronic circuit, while avoiding any damages to the LED module.

In an embodiment, the protection and/or the support structures of the tool have associated at least one flexible spring.

In an embodiment, which may be useful for electronic circuits comprising a plurality of LED devices, the protection is mobile and the support is fixed. In fact, the inventors have recognized that exclusively mobile supports may have limitations when being applied to electronic circuits comprising more than 3 LED devices, because each lighting point may have a different height as a result of dimensional and process variables.

Thus the arrangement described herein provides encapsulation techniques suitable for compensating dimensional tolerances and process variables. In this way, high reliability and mechanic stability of the electronic circuit may be guaranteed, while ensuring that the light emitting surface of the LED device(s) is left uncovered.

### BRIEF DESCRIPTION OF THE DRAWINGS

Embodiments will now be described, by way of example only, with reference to the drawings, wherein:

FIG. 1 shows an electronic circuit produced by a low-pressure, hot-melt moulding process;

FIG. 2 shows an injection tool for encapsulating an electronic circuit within an embodiment of the invention;

FIG. 3 shows an injection tool for encapsulating an electronic circuit within an embodiment of the invention;

FIG. 4 shows an injection tool for encapsulating an electronic circuit within an embodiment of the invention; and

FIG. 5 shows an injection tool for encapsulating an electronic circuit within an embodiment of the invention.

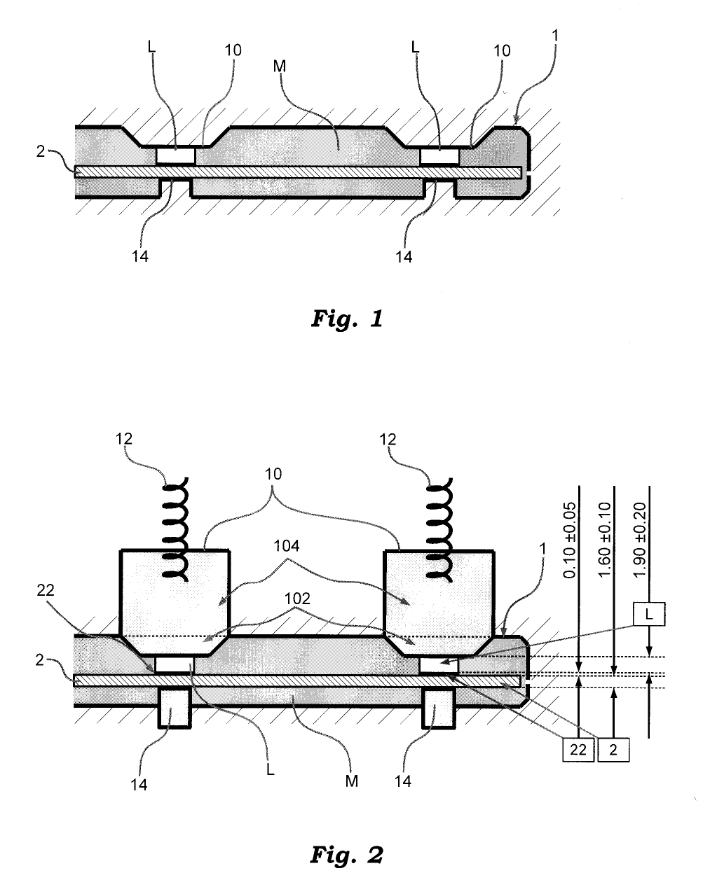

### DETAILED DESCRIPTION

In the following description, numerous specific details are given to provide a thorough understanding of embodiments. The embodiments can be practiced without one or more of the specific details, or with other methods, components, materials, etc. In other instances, well-known structures, materials, or operations are not shown or described in detail to avoid obscuring aspects of the embodiments.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The headings provided herein are for convenience only and do not interpret the scope or meaning of the embodiments.

FIG. 2 shows an injection tool for encapsulating an electronic circuit within an embodiment of the invention, including one mobile protection system 10 for each LED L as well as fixed supports 14.

As used herein, “mobile” denotes the possibility for the protection system (or at least the “distal” end thereof, facing the LED) to displace itself in order to allow for tolerances in manufacturing and/or positioning the LED and the PCB. Such an injection tool may compensate both components' dimension tolerances and process tolerances.

In the embodiment shown herein, the protection system 10 and the supports 14 are arranged to operate on opposite sides with respect to the electronic circuit.

In the embodiment shown herein, each protection system 10 is elastically biased (i.e. spring-loaded) against the LED L via an associated helical spring 12, which urges the protection system against the device.

In an embodiment, the force of the spring 12 may be adjusted, e.g. by means of an adjustable screw (not shown).

For example, in a typical embodiment, a force in the range between 0 and 10 kg may be set. In that way, it is possible to adjust the protection system independently for each device. Thus, it is even possible to reuse the same injection tool for electronic circuits comprising devices having different nominal heights.

After the electronic circuit has been inserted into the tool, the polyamide material M is injected.

In an embodiment, the encapsulation process comprises three phases:
1) injection of the melted material into the form in order to fill the cavities;
2) compensation in order to wait for a compensation of the shrinking effect of the injected material; and
3) cooling in order to decrease the temperature of the injected material.

In an embodiment, the tank which contains the melted material is kept at approximately 200° C., the injection heads have a temperature of approximately 215° C. and the tube between them has a temperature of approximately 210° C. In an embodiment, injection occurs with a pressure of 20 to 25 bar.

In the exemplary embodiment shown herein, the protection structure 10 comprises a tapered (e.g. frustum-like) portion 102 extending distally of a body portion 104 which is subjected to the action of the spring 12 in order to urge the portion 102 against the LED module L.

In an embodiment, the width of the portion 102 is selected sufficient large in order to avoid any significant influence of the encapsulation material on the light emission of the LED device L.

In the embodiment shown with respect to FIG. 2, the frustum-like portion 102 has a height, which is equal to the height of the molded PCB minus the maximum height the top surface of the LED device L may reach.

As already indicated, the term “mobile” is used herein to denote the possibility for the protection system 10 or at least the distal end thereof, facing the LED (e.g. the frustum-like portion 102) to displace itself in order to allow for tolerances in manufacturing and/or positioning the LED and the PCB. It will be appreciated that such mobility may be achieved by other means than those illustrated herein by way of example only: for instance, the mobility of a frustum-like portion as shown at 102 could be achieved by rendering the system 10 elastically compressible as a whole.

FIG. 2 shows an injection tool for encapsulating an electronic circuit within an embodiment of the invention, wherein tolerance values are shown for a PCB 2 having mounted thereon a LED device L by means of solder paste 22.

Typical component tolerances may include the height of the LED device L (e.g. 1.90±0.20 mm) and the thickness of the PCB 2 (e.g. 1.60±0.10 mm), and typical process tolerances may include the thickness of the solder paste layer 22 (e.g. 0.10±0.05 mm) or components' positions.

The maximum height H_{M} is the total sum of the components' nominal thickness and the sum of the maximum tolerances Vᵢ:

H_{M}=Tₙ+ΣVᵢ=Tₙ+P_{M}+SP_{M}+L_{M}

wherein H_{M} is the maximum height of the product including PCB 2, solder paste 22 and LED device L, Tₙ is the nominal height of the product including PCB 2, solder paste 22 and LED device L, P_{M} is the maximum positive tolerance for the height of the PCB 2, SP_{M} is the maximum positive tolerance of the thickness of the solder paste, and L_{M} is the maximum positive tolerance of the height of the LED package.

FIG. 3 shows an injection tool for encapsulating an electronic circuit within an embodiment of the invention, wherein the injection tool has the maximum height H_{M}, which means that the frustum-like portion 102 arrives exactly at the height of the molded electronic circuit, denominated in the following “zero level”. Specifically, for the exemplary nominal and tolerance values, the PCB 2 would have a thickness of 1.70 mm, the LED device L would have a height of 2.10 mm, and the solder paste would have a thickness of 0.15 mm, thus providing a maximum product's height H_{M} of 3.95 mm.

Conversely, when the components and materials have a height which is less than the maximum H_{M}, the frustum-like portion 102 immerges into the molded material M, and a visible step S is created, which does not exist for the “zero level” case.

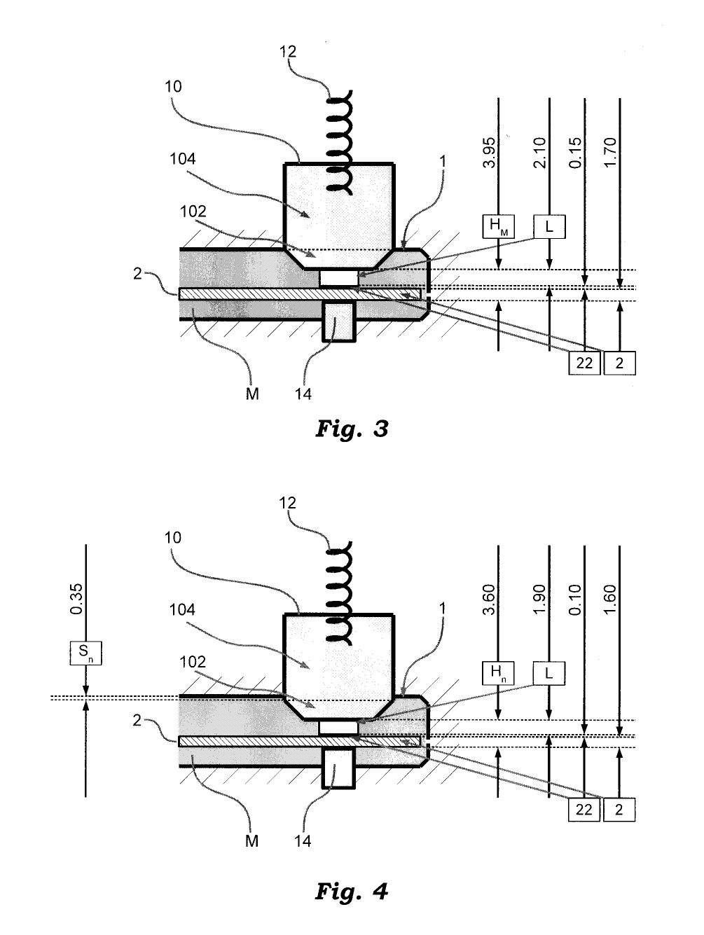

For example, FIG. 4 shows an injection tool for encapsulating an electronic circuit within an embodiment of the invention where all components have their nominal height or thickness, thus creating a step having the height Sₙ:

Sₙ=ΣVᵢ=P_{M}+SP_{M}+L_{M}

Specifically, for the exemplary nominal and tolerance values, the PCB 2 would have a thickness of 1.60 mm, the LED device L would have a height of 1.90 mm, and the solder paste would have a thickness of 0.10 mm, thus providing a nominal product's height Hₙ of 3.60 mm and a step height Sₙ of 0.35 mm.

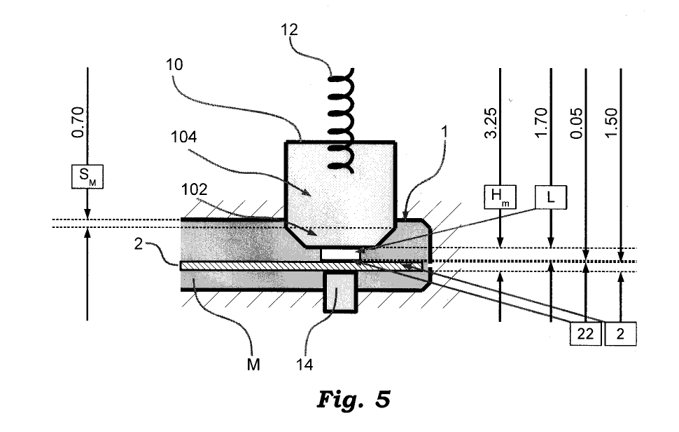

FIG. 5 shows an injection tool for encapsulating an electronic circuit within an embodiment of the invention, wherein all of the components have their minimum height or thickness, thus creating the maximum step height S_{M}:

S_{M}=2·Sₙ=2·(P_{M}+SP_{M}+L_{M})

Specifically, for the exemplary nominal and tolerance values, the PCB 2 would have a thickness of 1.50 mm, the LED device L would have a height of 1.70 mm, and the solder paste would have a thickness of 0.50 mm, thus providing a minimum product's height Hₘ of 3.25 mm and a maximum step height S_{M} of 0.70 mm.

In an embodiment, the “mobile” protection 10 may be used together with a flexible (i.e. again “mobile”) support structure 14, which further facilitates compensation of possible unevenness in the PCB 2.

In an embodiment, a “mobile” support structure 14 may be used in connection with one or more “fixed” protections 10. This embodiment may not create a variable step through the immersion of the portion 102 in the melted material; this embodiment may be useful for electronic circuits comprising less than three LED devices.

The above described arrangement of a mobile protection and/or support structure for an injection tools has several advantages. For example, the optical characteristics of the LED module are maintained, and the reliability and mechanical robustness is increased.

The arrangement adapts itself to dimensional tolerances in the components, such as PCB and driver components and LED device. The arrangement adapts itself also to dimensional tolerances resulting from process variables, such as solder paste deposition and reflow process.

Several of the embodiments described are able to adapt the tool for each individual light point.

Preferably, an adjustable elastic force is used for each light point, thus allowing to adapt the tool to the specific application requirements.

Those of skill in the art will appreciate that the arrangements described herein may be applied to any number of LED devices and to any type of injection tools.

Without prejudice to the underlying principles of the invention, the details and embodiments may vary, even significantly, with respect to what has been described herein merely by way of example, without departing from the scope of the invention as defined by the annexed claim.

1. An injection tool for encapsulating an electronic circuit with a printed circuit board and at least one light source arranged thereon, wherein the injection tool comprises:
a support structure configured to support the electronic circuit within the injection tool; and
a protection structure configured for protecting a light emitting surface of the at least one light source from encapsulation material,
wherein at least one of the support and/or protection structures is mobile, the at least one mobile structure configured to be displaced in compensating for dimensional tolerances in the electronic circuit.

2. The injection tool of claim 1, wherein the support structure is arranged on the opposite side of the electronic circuit that the protection structure is located.

3. The injection tool of claim 1, wherein at least one of the support and/or protection structures is elastically urged against the electronic circuit.

4. The injection tool of claim 3, wherein the at least one elastically urged structure is spring-biased against the electronic circuit.

5. The injection tool of claim 4, further comprising an adjustable spring to adjust the intensity of the spring bias applied to the at least one spring-biased structure.

6. The injection tool of claim 1, wherein at least one support structure and/or protection structure comprises a tapered portion facing the light emitting surface.

7. The injection tool of claim 6, wherein the tapered portion is frustum-shaped.

8. The injection tool of claim 1, wherein the support structure is fixed and the protection structures is mobile.

9. The injection tool of claim 1, wherein both of the support structure and protection structure are mobile.

10. The injection tool of claim 1, wherein the support structure is mobile and the protection structure is fixed.

11. The injection tool of claim 1, wherein the injection tool comprises a plurality of the support structures.

12. The injection tool of claim 1, wherein the injection tool comprises a plurality of the protection structures.

13. A process for encapsulating an electronic circuit including a printed circuit board and at least one light source arranged thereon, the process comprising:
providing an injection tool according to claim 1,
arranging the electronic circuit in the injection tool; and
injecting an encapsulation material into the injection tools, whereby the encapsulation material is prevented from reaching the light emitting surface of the at least one respective light source by the protection structure.

14. The process of claim 13, wherein the encapsulation material is injected into the injection tool by a low-pressure, hot-melt moulding process.

15. The process of claim 13, further comprising selecting a light emitting diode device as the at least one light source.
